(19) United States
(12) Patent Application Publication
(10) Pub. No.: US 2012/0205789 A1
(43) Pub. Date: Aug. 16, 2012

(54) SEMICONDUCTOR DEVICE AND METHOD OF MANUFACTURING THE SAME

(75) Inventors: Masanori NATSUAKI, Yokohama (JP); Seiji Ueno, Yokohama (JP); Takeshi Kodama, Yokohama (JP)

(73) Assignee: FUJITSU SEMICONDUCTOR LIMITED, Yokohama-shi (JP)

(21) Appl. No.: 13/325,779

(22) Filed: Dec. 14, 2011

(30) Foreign Application Priority Data
Feb. 14, 2011 (JP) 2011-028815

(51) Int. Cl. H01L 23/495; H01L 21/56; H01L 23/48

(52) U.S. Cl. 257/676; 257/773; 438/107; 257/E23.031; 257/E23.011; 257/E21.502

(57) ABSTRACT

In a semiconductor device, a first semiconductor element having a first terminal is embedded in a resin layer such that terminals thereof are exposed through a first surface of the resin layer. A wiring layer is formed in the first surface of the resin layer. A second semiconductor element includes second and third terminals. Regardless of the relationship between the plane size of the first semiconductor element and that of the second semiconductor element, the second terminal of the second semiconductor element is connected to the first terminal of the first semiconductor element exposed through the first surface of the resin layer, and the third terminal of the second semiconductor element is connected to the wiring layer formed in the resin layer.

### CROSS-REFERENCE TO RELATED APPLICATION

This application is based upon and claims the benefit of priority of the prior Japanese Patent Application No. 2011-028815, filed on Feb. 14, 2011, the entire contents of which are incorporated herein by reference.

### FIELD

The embodiments discussed herein are related to semiconductor devices and methods of manufacturing the same.

### BACKGROUND

Semiconductor devices are known which include chip-on-chip (COC) connection structures having a plurality of semiconductor elements (semiconductor chips) connected to each other using terminals such as bumps formed on surfaces (surfaces on which circuits are formed) of the semiconductor chips. Semiconductor devices are also known which include multichip layered structures having semiconductor elements connected to each other with tabular bodies interposed therebetween. The tabular bodies have predetermined sizes, and include, for example, feed-through electrodes and wiring lines formed thereon. In addition, semiconductor devices of, for example, the multichip type are also known which are formed by, for example, connecting a first semiconductor element disposed on one side of a conductor layer formed on a film to parts of the conductor layer, peeling the film, and connecting a second semiconductor element disposed on the other side of the conductor layer to parts of the conductor layer using wires.

### SUMMARY

According to an aspect of the present invention, a semiconductor device includes a first semiconductor element having a first terminal; a resin layer in which the first semiconductor element is embedded such that the first terminal is exposed through a first surface of the resin layer; a wiring layer formed in the first surface of the resin layer; and a second semiconductor element having a second terminal and a third terminal, the second terminal being formed on a surface of the second semiconductor element adjacent to the first surface and being connected to the first terminal, the third terminal being connected to the wiring layer.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B illustrate example structures of semiconductor devices;

FIG. 2 is a schematic cross-sectional view of an example semiconductor device according to a first embodiment;

FIG. 3 is a schematic plan view of the example semiconductor device according to the first embodiment;

FIG. 4 is a schematic cross-sectional view of a COC package of another form;

FIG. 5 is a schematic plan view of the COC package of the other form;

FIG. 6 illustrates another example of the semiconductor device according to the first embodiment;

FIGS. 7A and 7B illustrate a first example form of connection portions;

FIGS. 8A and 8B illustrate a second example form of the connection portions;

FIGS. 9A and 9B illustrate a third example form of the connection portions;

FIGS. 10A and 10B illustrate a fourth example form of the connection portions;

FIGS. 11A and 11B illustrate a fifth example form of the connection portions;

FIGS. 12A and 12B illustrate a sixth example form of the connection portions;

FIGS. 13A and 13B illustrate an example semiconductor device according to a second embodiment;

FIG. 14 illustrates another example of the semiconductor device according to the second embodiment;

FIGS. 15A and 15B illustrate an example semiconductor device according to a third embodiment;

FIGS. 16A and 16B illustrate an example semiconductor device according to a fourth embodiment;

FIG. 17 illustrates an example flow of forming semiconductor devices;

FIG. 18 is a first schematic cross-sectional view illustrating a step of forming the semiconductor devices;

FIGS. 19A, 19B, 19C, and 19D are second schematic cross-sectional views illustrating a step of forming the semiconductor devices;

FIG. 20 is a third schematic cross-sectional view illustrating a step of forming the semiconductor devices;

FIGS. 21A, 21B, 21C, and 21D are fourth schematic cross-sectional views illustrating a step of forming the semiconductor devices;

FIG. 22 is a fifth schematic cross-sectional view illustrating a step of forming the semiconductor devices;

FIG. 23 is a sixth schematic cross-sectional view illustrating a step of forming the semiconductor devices;

FIG. 24 is a seventh schematic cross-sectional view illustrating a step of forming the semiconductor devices;

FIG. 25 illustrates a first modification of a COC portion;

FIGS. 26A and 26B illustrate a second modification of the COC portion; and

FIG. 27 illustrates a modification of the COC package.

### DESCRIPTION OF EMBODIMENTS

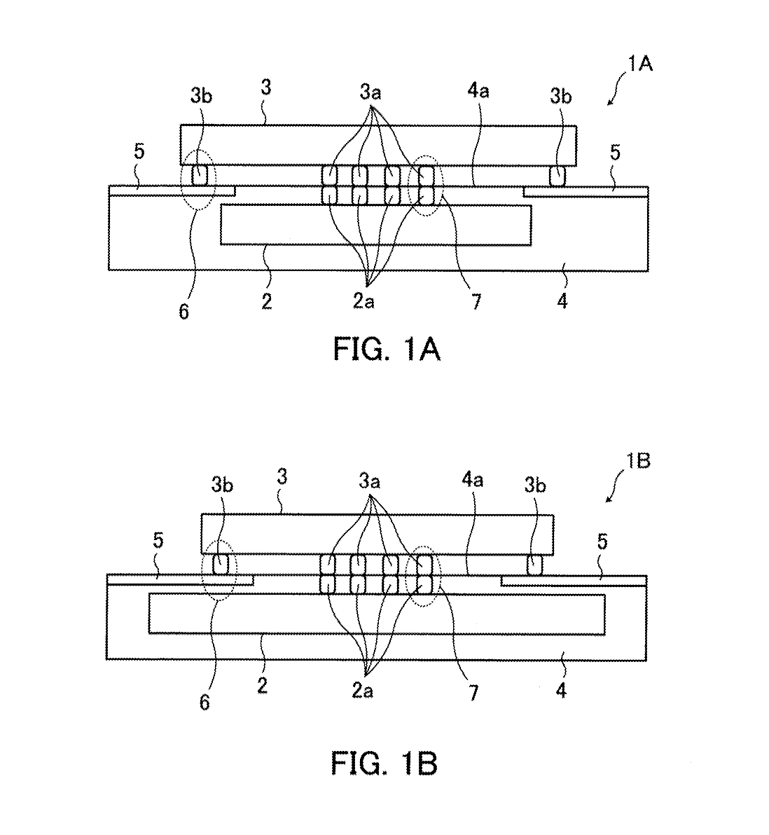

FIGS. 1A and 1B illustrate example structures of semiconductor devices including semiconductor elements. FIGS. 1A and 1B are schematic cross-sectional views of principal parts of the semiconductor devices. The relationships between the plane sizes of the connected semiconductor elements differ from each other in FIGS. 1A and 1B.

Semiconductor devices 1A and 1B illustrated in FIGS. 1A and 1B each include semiconductor elements 2 and 3, a resin layer 4, and a wiring layer 5. The semiconductor devices 1A and 1B differ from each other in the relationship between the plane size of the semiconductor element 2 and that of the semiconductor element 3. That is, the semiconductor element 2 is smaller than the semiconductor element 3 in the semiconductor device 1A, and the semiconductor element 2 is larger than the semiconductor element 3 in the semiconductor device 1B.

Each semiconductor element 2 has terminals 2a such as bumps. The semiconductor element 2 is embedded in the resin layer 4 such that the terminals 2a are exposed through a surface 4a of the resin layer 4. The wiring layer 5 is formed in the surface 4a of the resin layer 4.

Each semiconductor element 3 has terminals 3a and 3b such as bumps. The terminals 3a are formed, for example, at positions opposing the terminals 2a of the semiconductor element 2 exposed through the resin layer 4, and the terminals 3b are formed at positions opposing the wiring layer 5 formed in the surface 4a of the resin layer 4. The semiconductor element 3 is mounted on the resin layer 4 such that the terminals 3a are connected to the terminals 2a exposed through the resin layer 4 and such that the terminals 3b are connected to the wiring layer 5 in the resin layer 4.

The plane size of the resin layer 4 in which the semiconductor element 2 is embedded may be changed in accordance with the plane size of the semiconductor element 3 mounted on the resin layer 4. In addition, the pattern, namely length, shape, and other parameters, of the wiring layer 5 formed in the resin layer 4 may be changed in accordance with the plane size of the semiconductor element 3 mounted on the resin layer 4.

The semiconductor element 3 in the semiconductor devices 1A and 1B is able to connect to the outside by using the wiring layer 5 connected to the semiconductor element 3 with the terminals 3b interposed therebetween. For example, the wiring layer 5 is used as an area to be connected to an end of a wire for wire connection.

The semiconductor devices 1A and 1B each include portions (chip-on-board (COB) connection portions) 6 at which the semiconductor element 3 is connected to the wiring layer 5 with the terminals 3b interposed therebetween and portions (COC connection portions) 7 at which the semiconductor elements 2 and 3 are connected to each other by the terminals 2a of the semiconductor element 2 and the terminals 3a of the semiconductor element 3. The connection of the terminals 2a and 3a as observed at the COC connection portions 7 is effective in increasing the signal transmission speed between the semiconductor elements 2 and 3, and furthermore, also effective in miniaturizing the terminals 2a and 3a and in increasing the number of pins for finer pitches.

FIG. 1A illustrates a case where the semiconductor element 2 is smaller than the semiconductor element 3, and FIG. 1B illustrates a case where the semiconductor element 2 is larger than the semiconductor element 3. Even when the semiconductor elements 2 and 3 have the same plane size, a semiconductor device may include COB connection portions 6 and COC connection portions 7 similar to those described above in accordance with the examples illustrated in FIGS. 1A and 1B.

According to the above-described structure, a semiconductor device may include COC connection portions at which both semiconductor elements are connected to each other by terminals thereof and COB connection portions at which one of the semiconductor elements is connected to a wiring layer that is connectable to the outside via the terminals thereof regardless of the relationship between the plane sizes of the connected semiconductor elements.

The semiconductor device including the COC connection portions and the COB connection portions will now be described in more detail.

First, a first embodiment will be described.

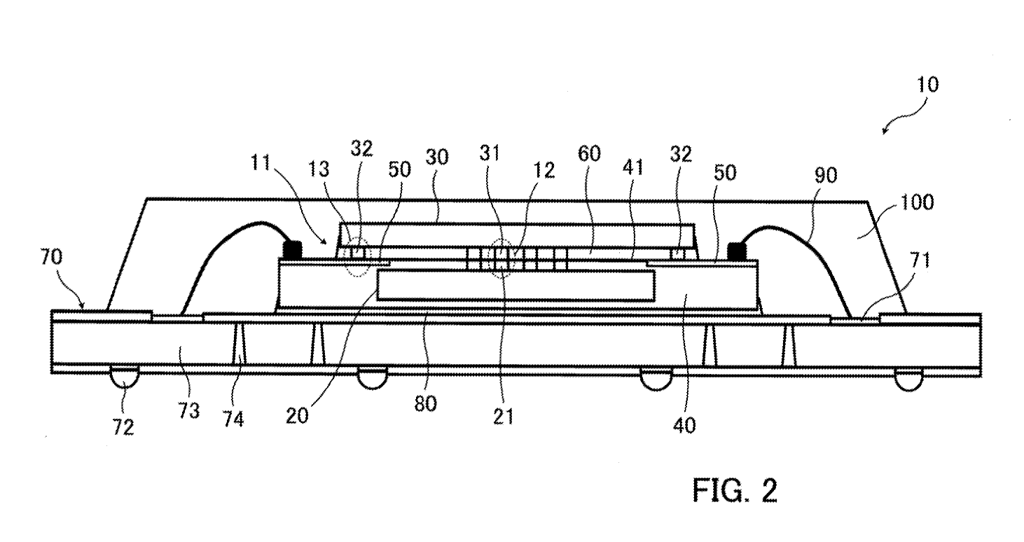

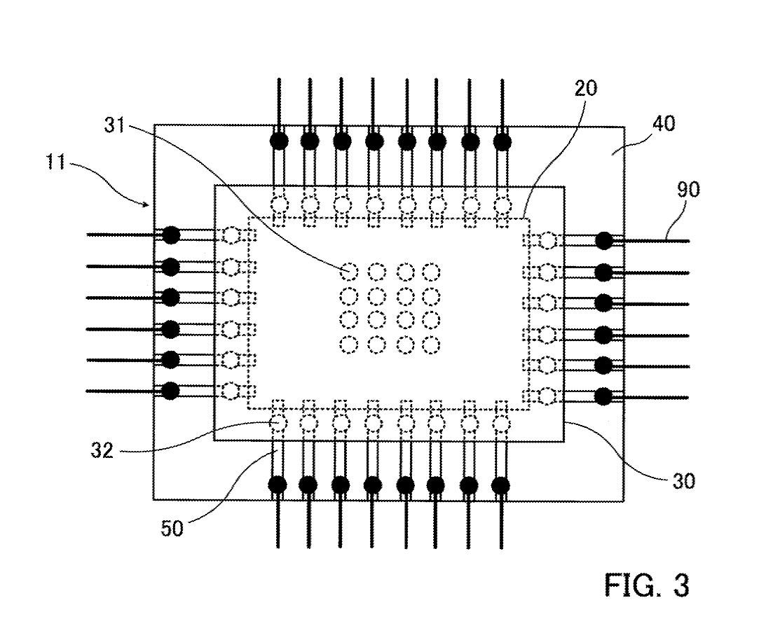

FIGS. 2 and 3 illustrate an example semiconductor device according to the first embodiment. FIG. 2 is a schematic cross-sectional view of the example semiconductor device according to the first embodiment, and FIG. 3 is a schematic plan view of a principal part of the example semiconductor device according to the first embodiment.

As illustrated in FIG. 2, a semiconductor device (COC package) 10 includes a structure (COC portion; semiconductor device) 11 including semiconductor elements (semiconductor chips) 20 and 30, a resin layer 40 in which the semiconductor chip 20 is embedded, a wiring layer 50, and a filler resin 60 that is applied between the chips. The semiconductor device 10 further includes a circuit board (interposer portion) 70, a die attachment member 80, wires 90, and a sealing resin 100.

First, the COC portion 11 will be described with reference to FIGS. 2 and 3. FIG. 3 illustrates a schematic plan view of the COC portion 11 in the COC package 10, and does not illustrate the filler resin 60, the interposer portion 70, the die attachment member 80, and the sealing resin 100 illustrated in FIG. 2.

The semiconductor chip 20 includes, for example, a semiconductor substrate, elements such as transistors formed on the semiconductor substrate, and a wiring layer including wiring lines and vias electrically connected to the elements, and has terminals (COC connection terminals) on a surface (circuit surface) on which the elements and the wiring layer are formed. The semiconductor chip is embedded in the resin layer 40 such that the COC connection terminals 21 are exposed through surface 41 of the resin layer 40 in a face-up position. The wiring layer 50 is formed in the surface 41 of the resin layer 40 so as to protrude outside the semiconductor chip 30 mounted on the resin layer 40.

As an example, the semiconductor chip 30 herein has a plane size larger than that of the semiconductor chip 20 embedded in the resin layer 40. The semiconductor chip 30 has terminals (COC connection terminals) 31 and terminals (COB connection terminals) 32 formed on a surface adjacent to the circuit surface. The COC connection terminals 31 are formed at positions opposing the COC connection terminals 21 of the semiconductor chip 20 exposed through the resin layer 40, and the COB connection terminals 32 are formed at positions opposing the wiring layer 50 formed in the surface 41 of the resin layer 40. The semiconductor chip 30 is mounted on the resin layer 40 in a face-down position such that the COC connection terminals 31 are directly connected to the COC connection terminals 21 of the semiconductor chip 20 and such that the COB connection terminals 32 are directly connected to the wiring layer 50 in the resin layer 40.

That is, the COC portion 11 includes COC connection portions 12 at which the semiconductor chips 20 and 30 are connected to each other by the COC connection terminals 21 and 31 and COB connection portions 13 at which the COB connection terminals 32 of the semiconductor chip 30 are connected to the wiring layer 50 in the resin layer 40.

As illustrated in FIG. 2, the filler resin 60 is formed between the semiconductor chips 20 and 30 in the COC portion 11. This filler resin 60 improves reliability of connection between the semiconductor chips 20 and 30.

The COC portion 11 having the above-described structure is mounted over the interposer portion 70 with the die attachment member 80 interposed therebetween.

The interposer portion 70 includes bonding pads 71 used for the connection with the COC portion 11, external-connection terminals (solder balls) 72, an insulating portion 73, feed-through electrodes (vias) 74, and other wiring patterns (not shown). The bonding pads 71 of the interposer portion 70 is connected (wire-bonded) to the wiring layer 50 extending from the COB connection portions 13 in the COC portion 11 by the wires 90.

The COC portion 11 mounted on and wire-bonded to the interposer portion 70 is sealed by the sealing resin 100 together with the wires 90.

In this COC package 10, the semiconductor chip may be, for example, 100 to 400 μm thick. The COC connection terminals 21 of the semiconductor chip 20 may be, for example, 10 to 30 μm high. The resin layer 40 may be, for example, 200 to 500 μm thick in accordance with the thickness of the semiconductor chip 20 to be embedded in the resin layer 40. The wiring layer 50 formed in the resin layer 40 may be, for example, 5 to 20 μm thick. The semiconductor chip 30 may be, for example, 70 to 200 μm thick. The COC connection terminals 31 and the COB connection terminals 32 of the semiconductor chip 30 may be, for example, 10 to 30 μm high. The filler resin 60 disposed between the semiconductor chips 20 and 30 may be, for example, 10 to 30 μm thick.

A multibus memory device (daughter chip), for example, may be used as the semiconductor chip 20 in the COC portion 11, and a logic device (mother chip) that exchanges data with the memory device, for example, may be used as the semiconductor chip 30. In this case, the semiconductor chip 20 serving as the daughter chip and the semiconductor chip 30 serving as the mother chip are connected to each other at the COC connection portions 12 by the connection of the COC connection terminals 21 and 31. Furthermore, the semiconductor chip 30 serving as the mother chip is connected to the wiring layer 50 at the COB connection portions 13, and the wiring layer 50 is connected to the bonding pads 71 of the interposer portion 70 by the wires 90. With this, the semiconductor chip 30 becomes connectable to the outside.

The restriction on the plane sizes of the semiconductor chips 20 and 30 is avoided in accordance with the COC package 10 described above, resulting in an improvement in flexibility in selecting the semiconductor chips 20 and 30 to be used and, furthermore, an improvement in flexibility in designing the COC package 10.

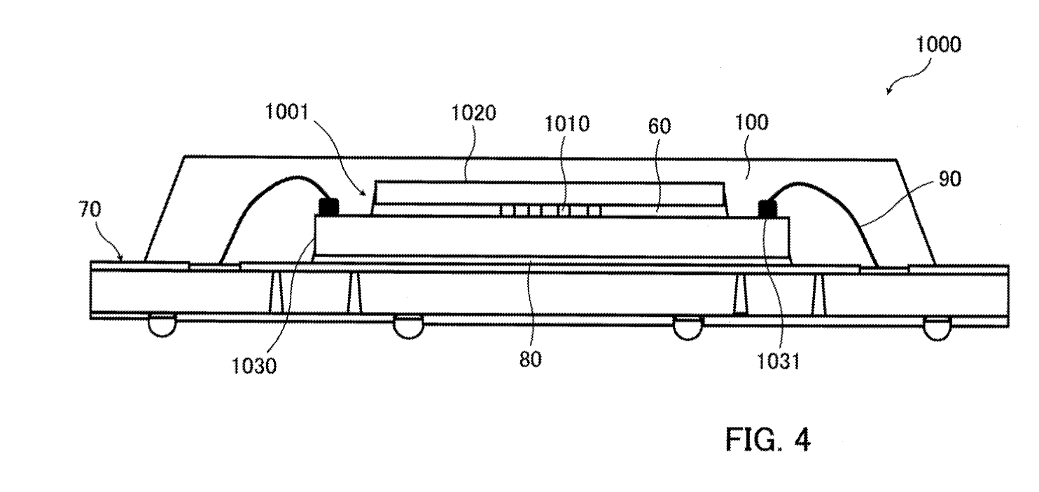

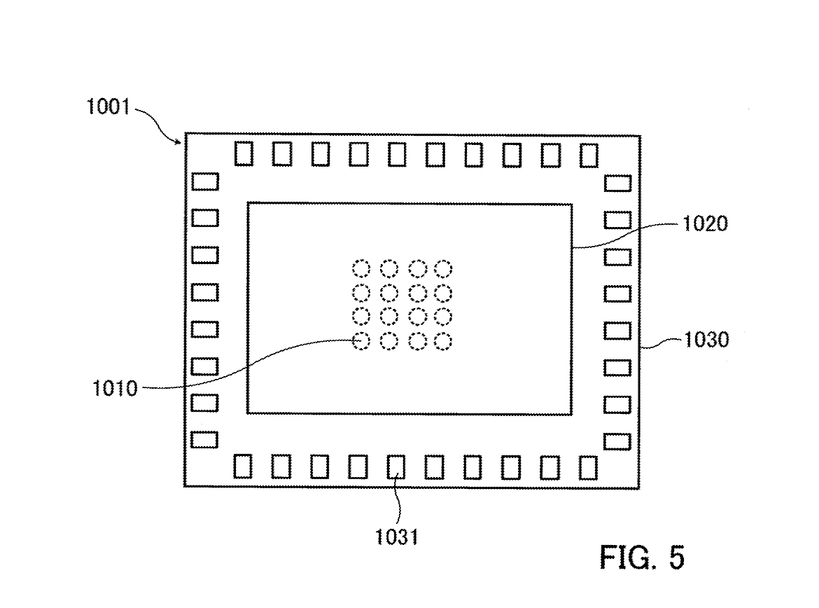

FIGS. 4 and 5 illustrate a COC package of another form. FIG. 4 is a schematic cross-sectional view of the COC package of the other form, and FIG. 5 is a schematic plan view of a COC portion in the COC package of the other form.

A COC package 1000 illustrated in FIGS. 4 and 5 includes a COC portion 1001 including a semiconductor chip 1030 serving as a mother chip, a semiconductor chip 1020 serving as a daughter chip disposed over the semiconductor chip 1030, and connection terminals 1010 that connect the semiconductor chip 1030 to the semiconductor chip 1020. A filler resin 60 is disposed between the semiconductor chips 1020 and 1030. The COC portion 1001 is mounted over an interposer portion 70 with a die attachment member 80 interposed therebetween while the semiconductor chip 1030 is located below the semiconductor chip 1020, and sealed by a sealing resin 100 after the semiconductor chip 1030 is connected to the interposer portion 70 by wires 90.

In this COC package 1000, the semiconductor chip 1030 is disposed below the semiconductor chip 1020 (adjacent to the interposer portion 70) while a circuit surface of the semiconductor chip 1030 faces upward in order to connect the wires 90 to the semiconductor chip 1030 that is to be connected to the outside. Furthermore, the semiconductor chip 1020 has a plane size with which connection areas 1031 for the wires 90 are left on the semiconductor chip 1030, that is, the semiconductor chip 1020 has a plane size that is small enough to stay inside the connection areas 1031 of the semiconductor chip 1030. A semiconductor chip 1020 having a size larger than or equal to that of the semiconductor chip 1030 may not be used in the COC package 1000 having the above-described structure, that is, the relationship between the plane size of the available semiconductor chip 1020 and that of the semiconductor chip 1030 is restricted.

When the semiconductor chip 1020 has a plane size larger than that of the semiconductor chip 1030, the following measure may be taken. That is, although not illustrated, rewiring lines, to be connected to external-connection terminals of the semiconductor chip 1030 and connectable to the wires 90, are formed on a circuit surface of a larger semiconductor chip 1020, and the vertical positional relationship between the semiconductor chips 1020 and 1030 is reversed. Subsequently, the rewiring lines formed on the semiconductor chip 1020 to be disposed below the semiconductor chip 1030 are connected to the interposer portion 70 by the wires 90. In this case, however, the rewiring lines need to be formed on the semiconductor chip 1020, and this may increase the cost and the number of processes. In addition, some forms of semiconductor chips 1020 may make it difficult for the rewiring lines to be formed, and may also require, for example, design changes for rewiring and review of production processes of the semiconductor chip 1020 as a result of the design changes.

When the semiconductor chips 1020 and 1030 have the same plane size, the following measures may be taken. That is, the semiconductor chip 1030 to be disposed below the semiconductor chip 1020 may be increased in size without changing the functions so that the wires 90 become connectable to the semiconductor chip 1030, or, when the semiconductor chip 1020 is a memory device, the semiconductor chip 1020 may be reduced in size by reducing the capacity. Alternatively, a tabular body such as a silicon (Si) spacer having a predetermined size may be disposed between the semiconductor chips 1020 and 1030. The tabular body may have appropriate wiring lines, vias, and connection areas connectable to the wires 90. In this case, however, there is a possibility of design restrictions and an increase in cost, and furthermore, the obtained COC package 1000 may not be provided with desired functions. In addition, the package size (height) is increased by placing the additional tabular body between the semiconductor chips 1020 and 1030.

In contrast, in the COC package 10 as illustrated in FIGS. 2 and 3, the semiconductor chip 20 serving as a daughter chip is embedded in the resin layer 40 such that the COC connection terminals 21 are exposed through the resin layer 40, and the semiconductor chip 30 serving as a mother chip is disposed over the semiconductor chip 20. The semiconductor chips 20 and 30 are connected to each other by the connection of the COC connection terminals 21 and 31, and the COB connection terminals 32 of the semiconductor chip 30 are connected to the wiring layer 50 formed in the resin layer 40. The wires 90 are connected to the wiring layer 50.

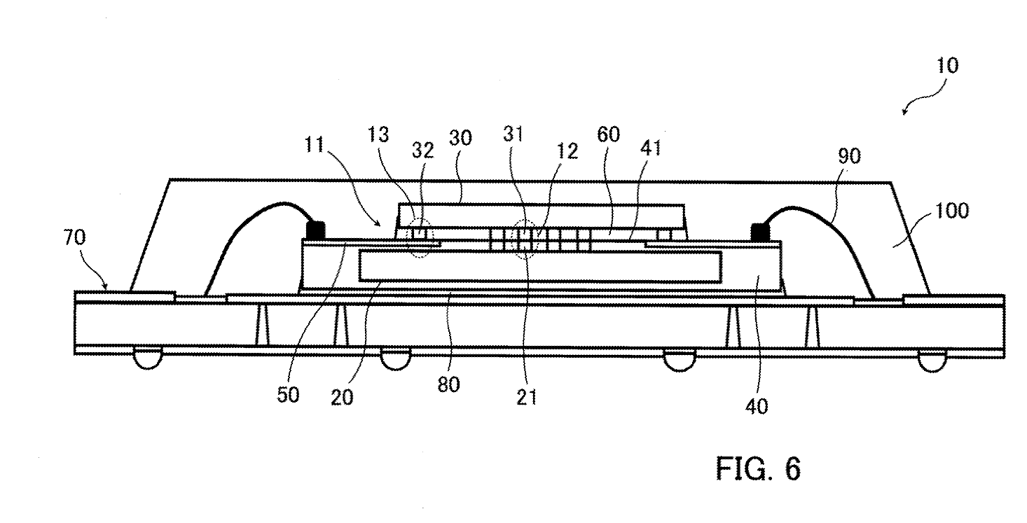

As a result, the restriction on the plane sizes of the semiconductor chips 20 and 30 is avoided in this structure. For example, when the semiconductor chip 20 has a plane size smaller than that of the semiconductor chip 30, the COC package will have a structure as illustrated in FIG. 2. That is, the semiconductor chips and 30 are connected to each other (COC connection portions 12), and the semiconductor chip 30 is connected to the wiring layer 50 for external connection (COB connection portions 13). Meanwhile, when the semiconductor chip 20 has a plane size larger than that of the semiconductor chip 30, the COC package may have a structure as illustrated in, for example, FIG. 6 described below.

FIG. 6 illustrates another example of the semiconductor device according to the first embodiment.

As illustrated in FIG. 6, the COC package 10 may have a structure similar to that illustrated in FIG. 2 even when the semiconductor chip 20 has a plane size larger than that of the semiconductor chip 30. That is, the semiconductor chip 20 is also embedded in the resin layer 40 in the COC package 10 illustrated in FIG. 6. The semiconductor chips 20 and 30 are connected to each other (COC connection portions 12), and the semiconductor chip is connected to the wiring layer 50 for external connection (COB connection portions 13).

The COC package may also have a similar structure even when the semiconductor chips 20 and 30 have the same plane size.

The plane size of the resin layer 40 or the pattern of the wiring layer 50 may be changed in accordance with the plane sizes of the semiconductor chips and 30 to be used so that the COC package 10 has a structure as illustrated in FIGS. 2 and 6.

Consequently, the semiconductor chips 20 and 30 in the COC package 10 may be connected to each other and may be connected to the outside regardless of the plane sizes of the semiconductor chips 20 and 30. The internal structures (for example, wiring lines, vias, and rewiring lines) or the processing functions of the semiconductor chips 20 and 30 to be used do not necessarily need to be changed. Therefore, the COC package 10 may be provided with desired functions without increasing the risk of design changes or an increase in cost.

Various forms of terminals may be applied to the COC connection portions 12 and the COB connection portions 13 in the above-described COC package 10.

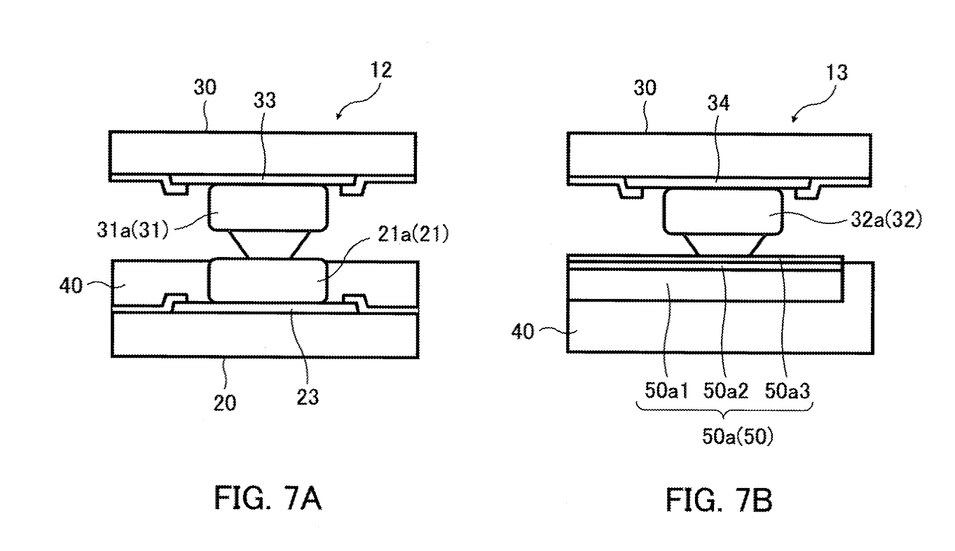

FIGS. 7A to 12B illustrate example forms of connection portions. FIGS. 7A, 8A, 9A, 10A, 11A, and 12A illustrate example forms of a COC connection portion 12, and FIGS. 7B, 8B, 9B, 10B, 11B, and 12B illustrate example forms of a COB connection portion 13.

As illustrated in FIG. 7A, a gold (Au) bump 21a may be used as the COC connection terminal 21 formed on a pad 23 on the semiconductor chip 20 embedded in the resin layer 40 in the COC connection portion 12. Similarly, a Au bump 31a may be used as the COC connection terminal 31 formed on a pad 33 on the semiconductor chip 30. In the COC connection portion 12 illustrated in FIG. 7A, the Au bumps 21a and 31a are connected to each other. Meanwhile, as illustrated in FIG. 7B, a copper (Cu)/nickel (Ni)/Au layer 50a including a Cu layer 50a1, a Ni layer 50a2, and a Au layer 50a3 laminated in this order may be used as the wiring layer 50 formed in the resin layer 40 in the COB connection portion 13. A Au bump 32a may be used as the COB connection terminal 32 formed on a pad 34 on the semiconductor chip 30. The Cu/Ni/Au layer 50a and the Au bump 32a are connected to each other in the COB connection portion 13 illustrated in FIG. 7B.

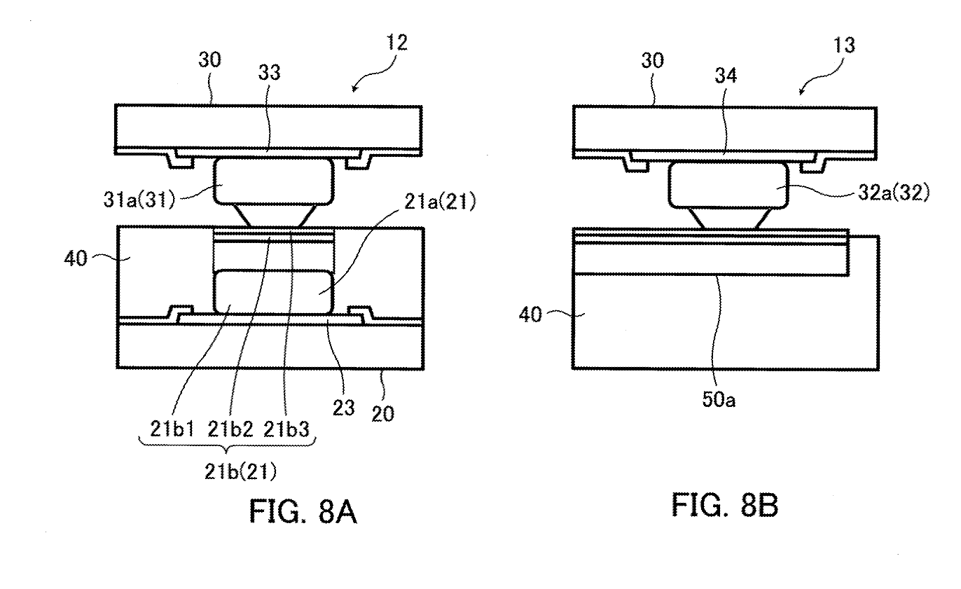

As illustrated in FIG. 8A, a layered structure including the Au bump 21a and a Cu/Ni/Au layer 21b including a Cu layer 21b1, a Ni layer 21b2, and a Au layer 21b3 may be used as the COC connection terminal 21 of the semiconductor chip 20 in the COC connection portion 12. The Au bump 31a may be used as the COC connection terminal of the semiconductor chip 30. In the COC connection portion 12 illustrated in FIG. 8A, the layered structure including the Au bump 21a and the Cu/Ni/Au layer 21b is connected to the Au bump 31a. Meanwhile, as illustrated in FIG. 8B, the Cu/Ni/Au layer 50a may be used for the semiconductor chip 20, and the Au bump 32a may be used for the semiconductor chip 30 in the COB connection portion 13. The Cu/Ni/Au layer 50a and the Au bump 32a are connected to each other.

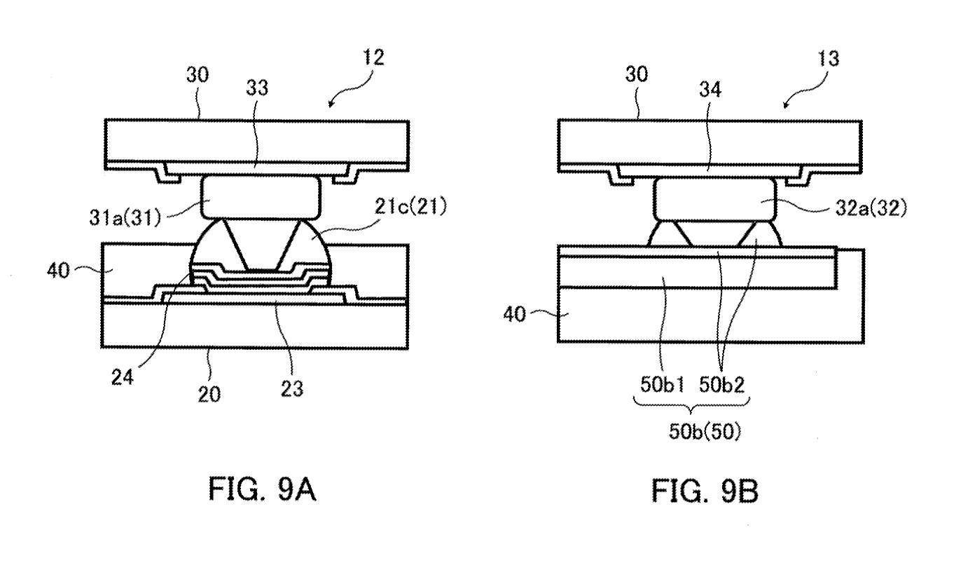

As illustrated in FIG. 9A, a solder bump 21c formed over the semiconductor chip 20 with, for example, an under-bump metal (UBM) 24 interposed therebetween may be used as the COC connection terminal 21 of the semiconductor chip 20 in the COC connection portion 12. The Au bump 31a may be used as the COC connection terminal 31 of the semiconductor chip 30. The solder bump 21c and the Au bump 31a are connected to each other in the COC connection portion 12 illustrated in FIG. 9A. Meanwhile, as illustrated in FIG. 9B, a Cu/solder layer 50b including a Cu layer 50b1 and solder layers 50b2 laminated thereon may be used as the wiring layer 50 in the COB connection portion 13. The Au bump 32a may be used as the COB connection terminal 32 of the semiconductor chip 30. In the COB connection portion 13 illustrated in FIG. 9B, the Cu/solder layer 50b and the Au bump 32a are connected to each other.

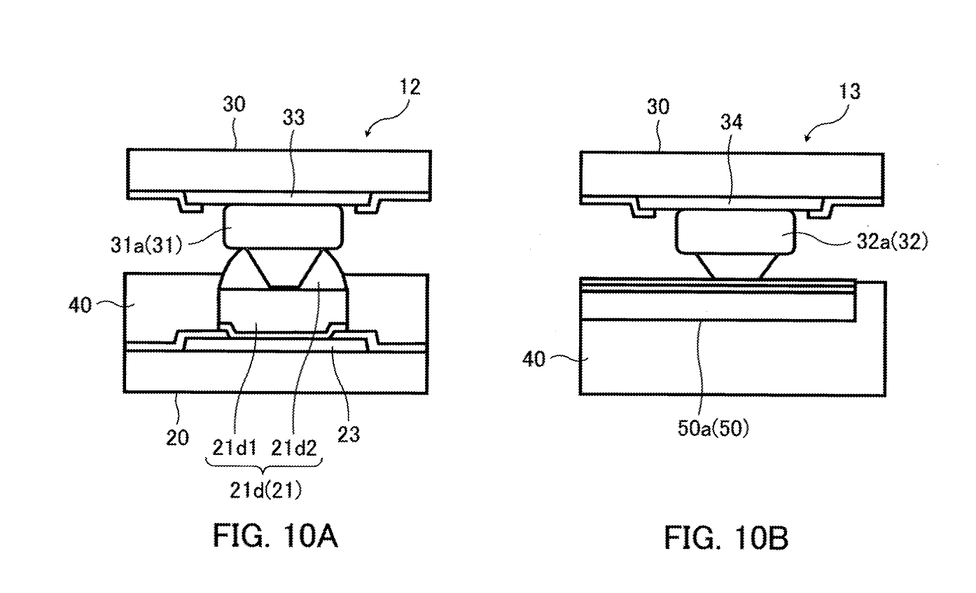

As illustrated in FIG. 10A, a pillar electrode 21d including a Cu pillar 21d1 and a solder bump 21d2 formed thereon may be used as the COC connection terminal of the semiconductor chip 20 in the COC connection portion 12. The Au bump 31a may be used as the COC connection terminal 31 of the semiconductor chip 30. In the COC connection portion 12 illustrated in FIG. 10A, the pillar electrode 21d and the Au bump 31a are connected to each other. Meanwhile, as illustrated in FIG. 10B, the Cu/Ni/Au layer 50a may be used for the semiconductor chip 20, and the Au bump 32a may be used for the semiconductor chip 30 in the COB connection portion 13. The Cu/Ni/Au layer 50a and the Au bump 32a are connected to each other.

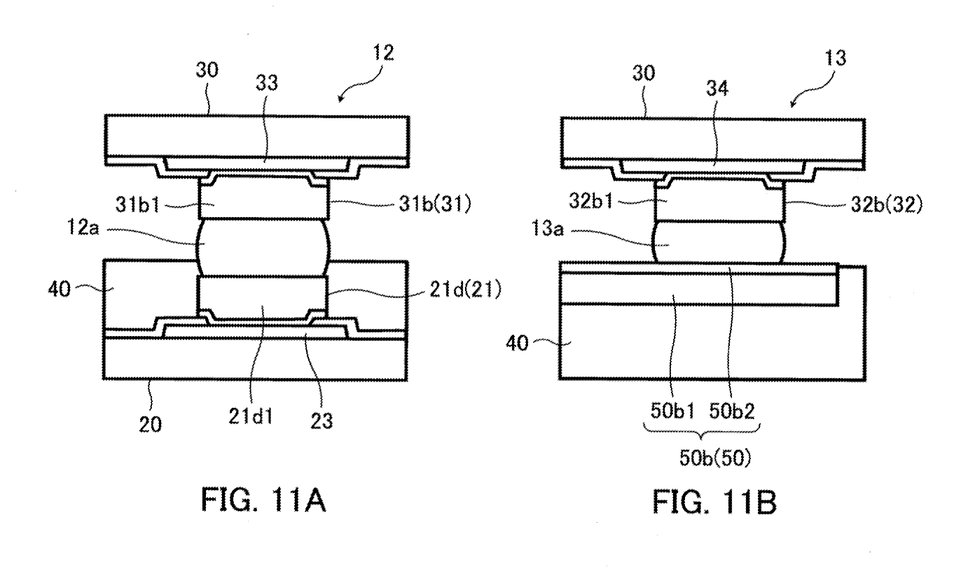

As illustrated in FIG. 11A, the pillar electrode 21d may be used as the COC connection terminal of the semiconductor chip 20 in the COC connection portion 12. Similarly, a pillar electrode 31b including a Cu pillar 31b1 and a solder bump formed thereon may be used as the COC connection terminal 31 of the semiconductor chip 30. In the COC connection portion 12 illustrated in FIG. 11A, the Cu pillar 21d1 of the pillar electrode 21d is connected to the Cu pillar 31b1 of the pillar electrode 31b by a solder bump 12a formed of the solder bumps on the Cu pillars 21d1 and 31b1 integrated with each other. Meanwhile, as illustrated in FIG. 11B, the Cu/solder layer 50b may be used as the wiring layer 50 in the COB connection portion 13. A pillar electrode 32b including a Cu pillar 32b1 and a solder bump formed thereon may be used as the COB connection terminal 32 of the semiconductor chip 30. In the COB connection portion 13 illustrated in FIG. 11B, the Cu layer 50b1 and the Cu pillar 32b1 are connected to each other by a solder bump 13a formed of the solder layer on the Cu layer 50b1 and the solder bump on the Cu pillar 32b1 integrated with each other.

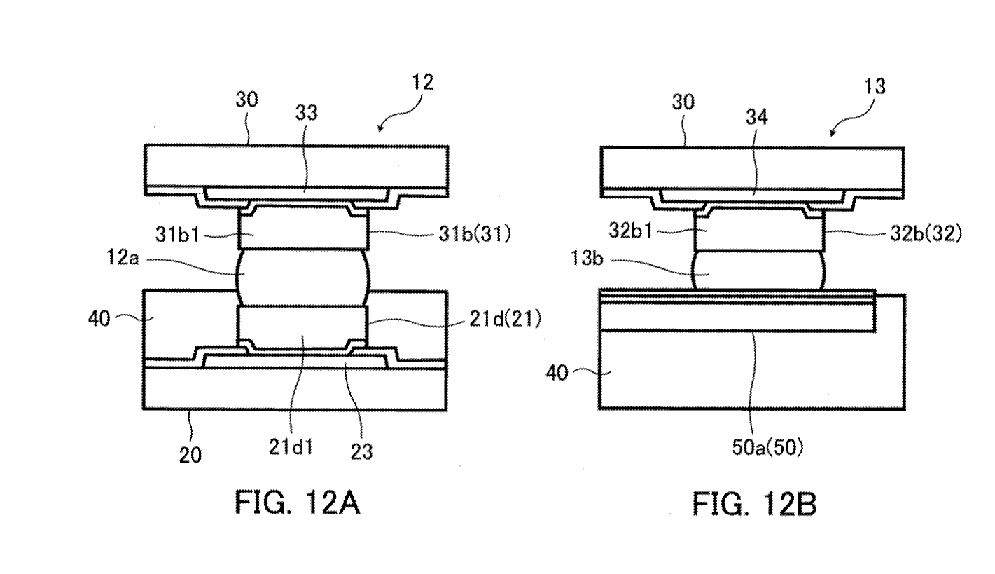

As illustrated in FIG. 12A, the pillar electrode 21d may be used as the COC connection terminal 21 of the semiconductor chip 20, and similarly, the pillar electrode 31b may be used as the COC connection terminal of the semiconductor chip 30 in the COC connection portion 12. In the COC connection portion 12 illustrated in FIG. 12A, the Cu pillars 21d1 and 31b1 are connected to each other by the solder bump 12a. Meanwhile, in the COB connection portion 13, as illustrated in FIG. 12B, the Cu/Ni/Au layer 50a may be used as the wiring layer 50, and the pillar electrode 32b may be used as the COB connection terminal 32 of the semiconductor chip 30. In the COB connection portion 13 illustrated in FIG. 12B, the Cu/Ni/Au layer 50a and the Cu pillar 32b1 are connected by a solder bump 13b.

The heights of the pillar electrodes 21d, 31b, and 32b may be controlled by adjusting conditions such as plating time during the formation of the pillar electrodes. Solder bumps may be used instead of the Au bumps 21a, 31a, and 32a.

The combinations of the COC connection portion 12 and the COB connection portion 13 illustrated in FIGS. 7A to 12B are merely examples, and other combinations may also constitute the COC connection portion 12 and the COB connection portion 13.

In the description above, the semiconductor chip 20 serving as a daughter chip is embedded in the resin layer 40 such that the COC connection terminals 21 are exposed through the resin layer 40, and the semiconductor chip 30 serving as a mother chip is mounted thereon.

Instead of this, the semiconductor chip 30 may be embedded in the resin layer 40 such that the COC connection terminals 31 are exposed through the resin layer 40, and the COB connection terminals 32 may be connected to the rear surface of the wiring layer 50 in the resin layer 40. Subsequently, the semiconductor chip may be mounted on the resin layer 40 in which the semiconductor chip 30 is embedded as described above such that the COC connection terminals 21 and 31 are connected to each other. In the COC portion having this structure, the restriction on the plane sizes of the semiconductor chips 20 and 30 may be avoided as in the COC portion 11 described above.

Next, a second embodiment will be described.

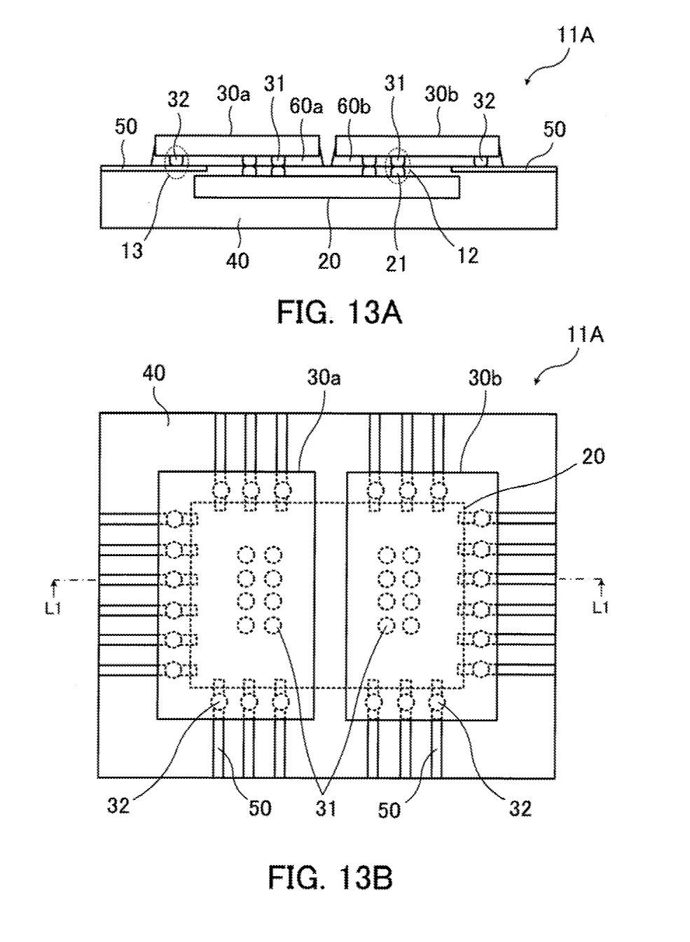

FIGS. 13A and 13B illustrate an example semiconductor device according to the second embodiment. FIG. 13A is a schematic cross-sectional view of a principal part of the example semiconductor device according to the second embodiment, and FIG. 13B is a schematic plan view of the principal part of the example semiconductor device according to the second embodiment. FIG. 13A is a cross-section taken along line L1-L1 in FIG. 13B.

FIGS. 13A and 13B illustrate a COC portion (semiconductor device) 11A including semiconductor chips 20, 30a, and 30b, a resin layer 40, a wiring layer 50, and filler resins 60a and 60b. As an example, both the semiconductor chips 30a and 30b are connected to the semiconductor chip 20 embedded in the resin layer 40 (COC connection portions 12) in the COC portion 11A. At the same time, the semiconductor chips 30a and 30b are connected to the wiring layer 50 formed in the resin layer (COB connection portions 13). The filler resin 60a is disposed between the semiconductor chip 30a and the resin layer 40, and the filler resin 60b is disposed between the semiconductor chip 30b and the resin layer 40. The COC portion 11A differs from the COC portion 11 according to the first embodiment in the above-described points.

A COC package is produced by mounting the COC portion 11A as illustrated in FIGS. 13A and 13B over an interposer portion 70 with a die attachment member 80 interposed therebetween as in the above-described case, and by sealing using a sealing resin 100 after the wiring layer 50 is connected to the interposer portion 70 by wires 90.

The restriction on the relationship between the plane size of the semiconductor chip 20 and those of the semiconductor chips 30a and 30b may also be avoided in the COC portion 11A having the above-described structure even when the semiconductor chip 20 is connected to both the semiconductor chips 30a and 30b.

Alternatively, the semiconductor chips 30a and 30b may be embedded in the resin layer 40 such that COC connection terminals 31 are exposed through the resin layer 40, and COB connection terminals 32 may be connected to the wiring layer 50 in the resin layer 40. Subsequently, the semiconductor chip 20 may be mounted on the resin layer 40 in which the semiconductor chips 30a and 30b are embedded as described above such that COC connection terminals 21 and the COC connection terminals 31 are connected to each other. In the COC portion having this structure, the restriction of the plane sizes of the semiconductor chips 20, 30a, and 30b may be avoided as in the COC portion 11A described above.

Both the semiconductor chips 30a and 30b are connected to the semiconductor chip 20 in the description above. However, the number of semiconductor chips to be connected to the semiconductor chip 20 is not limited to this. Effects similar to those described above may be produced even when two or more semiconductor chips are connected to the semiconductor chip 20 by adopting a structure similar to that of the COC portion 11A.

Although the semiconductor chip 20 is embedded in the resin layer 40 in the example illustrated in FIGS. 13A and 13B, a Si interposer (semiconductor element) may be embedded instead of the semiconductor chip 20.

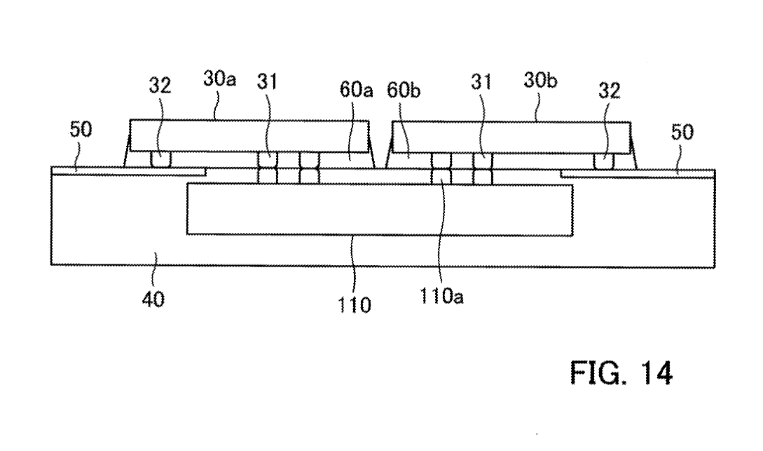

FIG. 14 illustrates another example of the semiconductor device according to the second embodiment. FIG. 14 is a schematic cross-sectional view of a principal part of the other example of the semiconductor device according to the second embodiment.

For example, a Si interposer 110 having wiring lines, vias (both not shown), and COC connection terminals 110a as illustrated in FIG. 14 is embedded in the resin layer 40 such that the COC connection terminals 110a are exposed through the resin layer 40. The semiconductor chips 30a and 30b are mounted on the resin layer 40 in which the Si interposer 110 are embedded as described above such that the COC connection terminals 110a and 31 are connected to each other.

The restriction on the relationship between the plane size of the Si interposer 110 and those of the semiconductor chips 30a and 30b may be avoided in the structure illustrated in FIG. 14, and the semiconductor chips 30a and 30b may be connected to each other via the Si interposer 110.

Next, a third embodiment will be described.

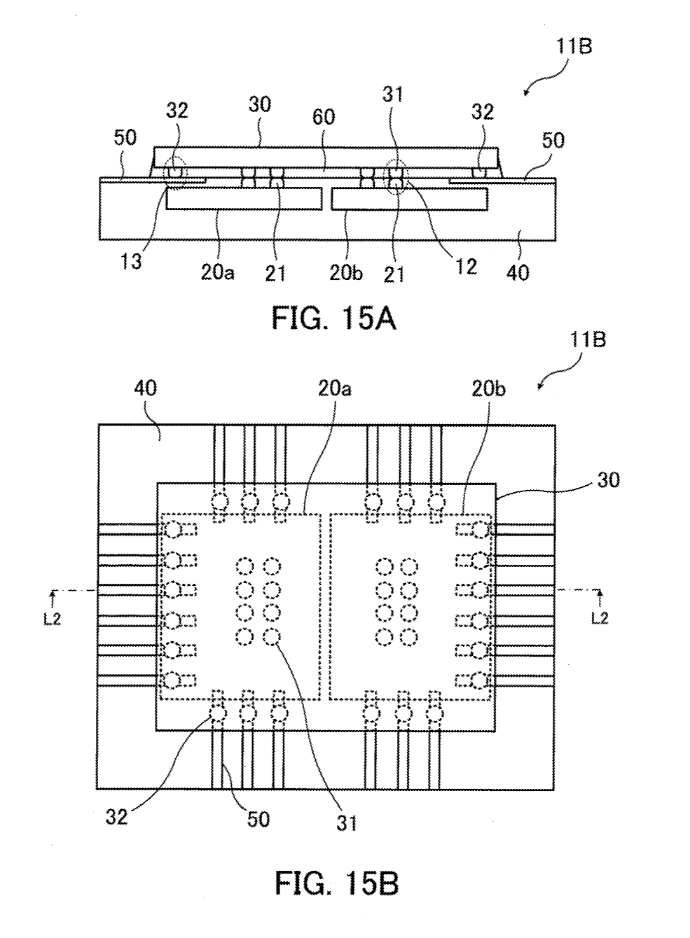

FIGS. 15A and 15B illustrate an example semiconductor device according to the third embodiment. FIG. 15A is a schematic cross-sectional view of a principal part of the example semiconductor device according to the third embodiment, and FIG. 15B is a schematic plan view of the principal part of the example semiconductor device according to the third embodiment. FIG. 15A is a cross-section taken along line L2-L2 in FIG. 15B.

FIGS. 15A and 15B illustrate a COC portion (semiconductor device) 11B including semiconductor chips 20a, 20b, and 30, a resin layer 40, a wiring layer 50, and a filler resin 60. As an example, the semiconductor chip is connected to both the semiconductor chips 20a and 20b embedded in the resin layer 40 (COC connection portions 12) in the COC portion 11B. At the same time, the semiconductor chip 30 is connected to the wiring layer 50 formed in the resin layer 40 (COB connection portions 13). The filler resin 60 is disposed between the semiconductor chip 30 and the resin layer 40. The COC portion 11B differs from the COC portion 11 according to the first embodiment in the above-described points.

A COC package is produced by mounting the COC portion 11B as illustrated in FIGS. 15A and 15B over an interposer portion 70 with a die attachment member 80 interposed therebetween as in the above-described case, and by sealing using a sealing resin 100 after the wiring layer 50 is connected to the interposer portion 70 by wires 90.

The restriction on the relationship between the plane sizes of the semiconductor chips 20a and 20b and that of the semiconductor chip 30 may be avoided in the COC portion 11B having the above-described structure.

Alternatively, the semiconductor chip 30 may be embedded in the resin layer 40 such that COC connection terminals 31 are exposed through the resin layer 40, and COB connection terminals 32 may be connected to the wiring layer 50 in the resin layer 40. The semiconductor chips 20a and 20b are mounted on the resin layer 40 in which the semiconductor chip 30 is embedded such that COC connection terminals 21, and the COC connection terminals 31 are connected to each other. In the COC portion having this structure, the restriction on the plane sizes of the semiconductor chips 20a, 20b, and 30 may be avoided as in the COC portion 11B described above.

The semiconductor chip 30 is connected to both the semiconductor chips 20a and 20b in the description above. However, the number of the semiconductor chips connected to the semiconductor chip 30 is not limited to this. Effects similar to those described above may be produced even when two or more semiconductor chips are connected to the semiconductor chip 30 by adopting a structure similar to that of the COC portion 11B.

For example, when a logic device is used as the semiconductor chip 30 and a memory device is used as the semiconductor chip to be connected to the semiconductor chip 30, the plane size or the number of the memory devices may be changed as appropriate so that the entire memory capacity may be changed. That is, when the structure as illustrated in FIG. 4 is adopted, a memory device (corresponding to the semiconductor chip 1020) having a plane size small enough to stay inside the surface of a logic device (corresponding to the semiconductor chip 1030) is required with consideration of external connection of the logic device. Alternatively, the number of the memory devices needs to be set such that the memory devices stay inside the surface of the logic device. In contrast, the restriction on the plane size of the logic device and that of the memory device or on the number of the memory devices is avoided by adopting the structure according to the third embodiment as illustrated in FIGS. 15A and 15B, thereby the plane size of the logic device and that of the memory device or the number of the memory devices may be changed as appropriate.

In addition, when a system-on-chip (SoC) is used as the semiconductor chip 30 and a microchip formed at a different technology node is used as the semiconductor chip to be connected to the semiconductor chip 30, the cost of the entire device may be reduced.

Next, a fourth embodiment will be described.

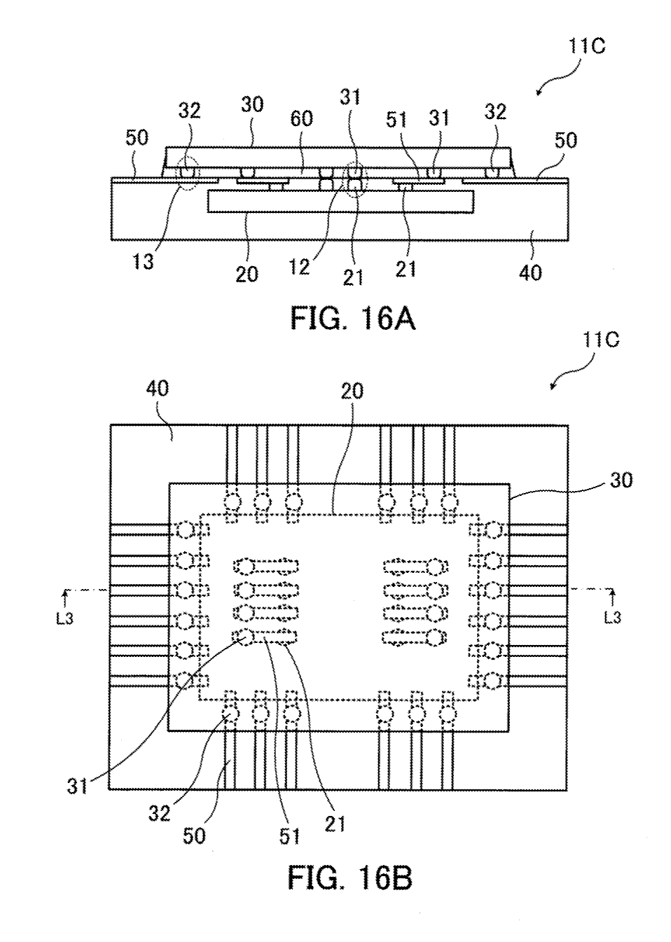

FIGS. 16A and 16B illustrate an example semiconductor device according to the fourth embodiment. FIG. 16A is a schematic cross-sectional view of a principal part of the example semiconductor device according to the fourth embodiment, and FIG. 16B is a schematic plan view of the principal part of the example semiconductor device according to the fourth embodiment. FIG. 16A is a cross-section taken along line L3-L3 in FIG. 16B.

FIGS. 16A and 16B illustrate a COC portion (semiconductor device) 11C including semiconductor chips 20 and 30, a resin layer 40, a wiring layer 50, another wiring layer (internally sealed terminal) 51, and a filler resin 60. In the COC portion 11C, some of COC connection terminals 21 and 31 are connected to each other by the internally sealed terminals 51. The COC portion 11C differs from the COC portion 11 according to the first embodiment in the above-described points.

A COC package is produced by mounting the COC portion 11C as illustrated in FIGS. 16A and 16B over an interposer portion 70 with a die attachment member 80 interposed therebetween as in the above-described case, and by sealing using a sealing resin 100 after the wiring layer 50 is connected to the interposer portion 70 by wires 90.

The restriction on the plane sizes of the semiconductor chips 20 and 30 may be avoided in the COC portion 11C having the above-described structure. Even when not all the COC connection terminals 21 of the semiconductor chip 20 and the COC connection terminals 31 of the semiconductor chip 30 are formed at positions opposing each other, the COC connection terminals 21 and that do not oppose each other are connected to each other by the internally sealed terminals 51 in the COC portion 11C having the above-described structure. This may improve flexibility in the combination of the semiconductor chips 20 and 30 to be used, and may improve flexibility in routing wiring lines in the semiconductor chips 20 and 30.

In addition, the semiconductor chip 30 may be embedded in the resin layer 40, and the semiconductor chip may be mounted on the resin layer 40 in the fourth embodiment.

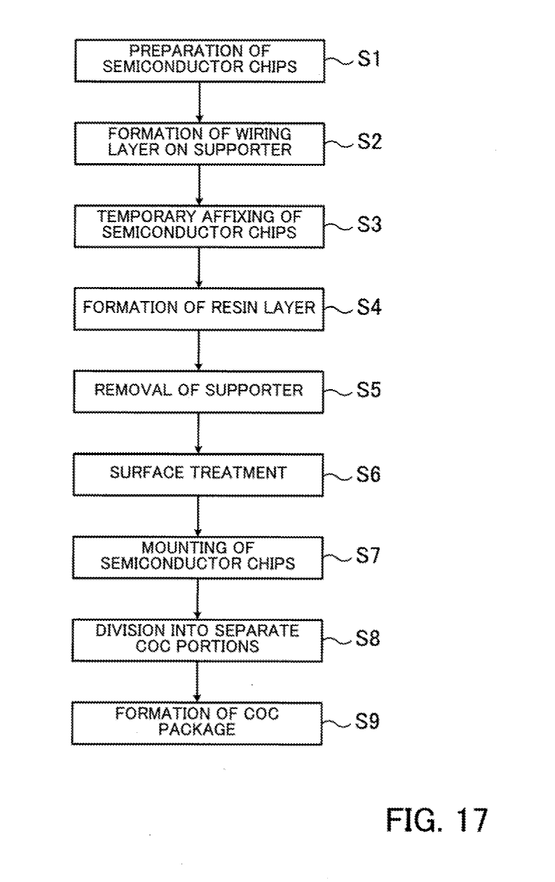

The semiconductor devices according to the first to fourth embodiments have been described above. Next, an example method of forming semiconductor devices will be described with reference to FIGS. 17 to 24.

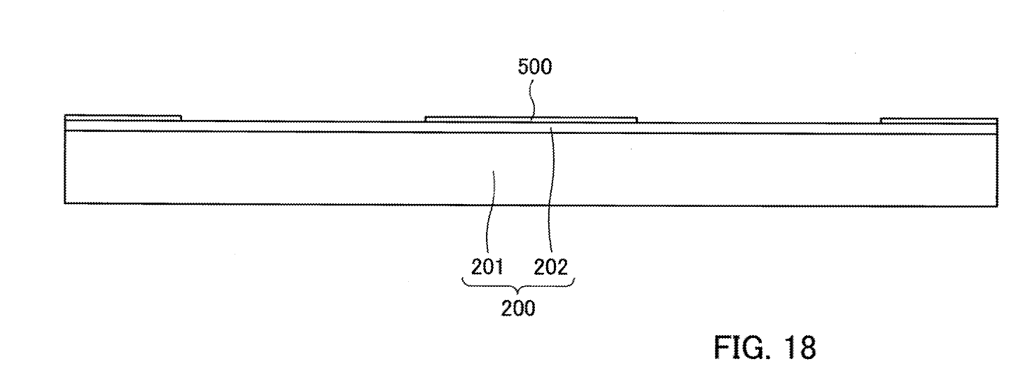

FIG. 17 illustrates an example flow of forming the semiconductor devices. FIGS. 18 to 24 illustrate steps of forming the semiconductor devices. FIGS. 18 to 24 are schematic cross-sectional views of principal parts of example forming steps.

Herein, a method of forming COC packages 10 according to the first embodiment will be described as an example. Steps after the formation of semiconductor chips 20 and 30 will be described in detail below.

First, the semiconductor chips 20 and 30 are prepared (Step S1). COC connection terminals 21 are formed on each semiconductor chip 20 such that the semiconductor chip 20 has a predetermined thickness, and COC connection terminals 31 and COB connection terminals 32 are formed on each semiconductor chip 30 such that the semiconductor chip 30 has a predetermined thickness.

Next, a wiring layer 500 is formed on a supporter 200 as illustrated in FIG. 18 (Step S2).

For example, a supporter of a layered structure capable of being selectively etched is used as the supporter 200. The supporter may include, for example, that of a two-layer structure including a Cu layer serving as a first layer 201 and a Ni layer serving as a second layer 202 (Cu/Ni supporter). Alternatively, the supporter 200 may include a supporter body serving as the first layer 201 and an adhesive layer, separably formed on a surface of the first layer 201, serving as the second layer 202. The wiring layer 500 is formed by forming a resist (not shown) on the above-described supporter 200, by patterning the resist so as to form openings in predetermined areas of the resist, and by, for example, plating copper. The resist is removed after the formation of the wiring layer 500.

When the supporter 200 is a Cu/Ni supporter and the wiring layer 500 is a Cu layer, the wiring layer 500 is formed on the Ni layer (second layer 202) of the Cu/Ni supporter. When the supporter 200 includes a supporter body (first layer 201) and an adhesive layer (second layer 202) formed thereon, a seed layer is formed on the adhesive layer by, for example, electroless copper plating and the wiring layer 500 is formed thereon.

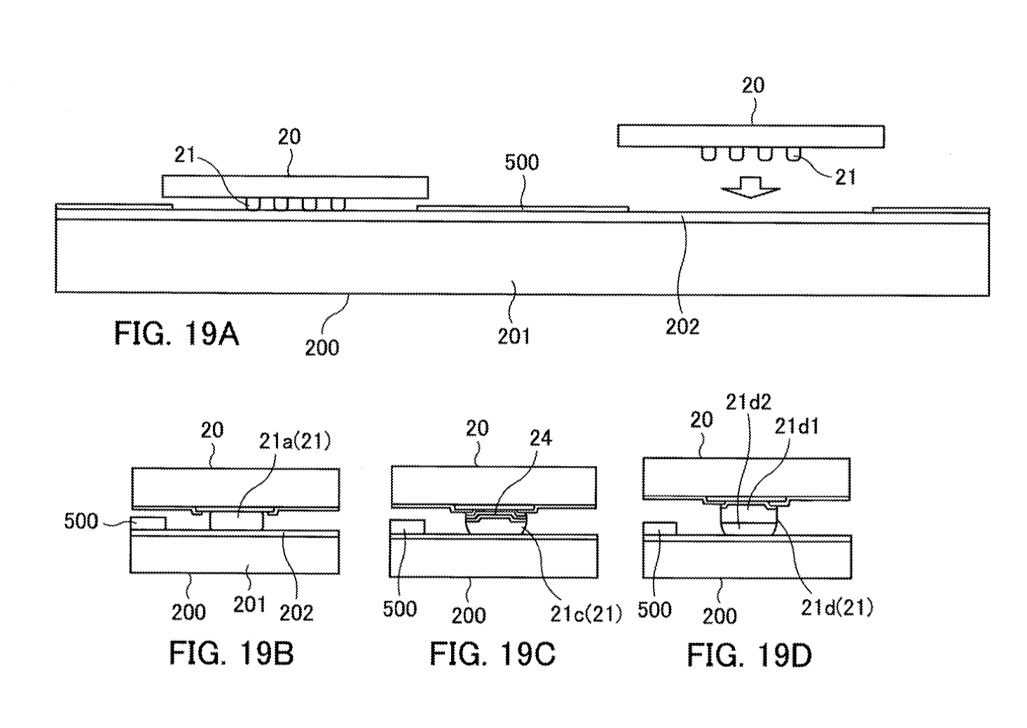

As illustrated in FIGS. 19A to 19D, the semiconductor chips 20 are temporarily affixed to the supporter 200 after the formation of the wiring layer 500 (Step S3).

As illustrated in FIG. 19A, the semiconductor chips 20 are positioned on a surface of the supporter 200 on which the wiring layer 500 is formed, and are temporarily affixed to the supporter 200 such that the COC connection terminals 21 thereof are brought into contact with the supporter 200 (second layer 202). The COC connection terminals 21 are temporarily affixed to the surface of the supporter 200 by, for example, heating under pressure. At this moment, the COC connection terminals 21 are leveled as illustrated in FIGS. 19B, 19C, and 19D (a Au bump 21a, a solder bump 21c, and a pillar electrodes 21d, respectively) by being heated under pressure so as to have a predetermined height.

Although not illustrated, non-conductive paste (NCP) or a non-conductive film (NCF) may be disposed in advance on an area to which the semiconductor chips 20 are to be temporarily affixed to the supporter 200. Alternatively, although not illustrated, a B-stage (semicured) film such as a NCF may be disposed in advance on an entire supporter surface to which the semiconductor chips 20 are to be temporarily affixed.

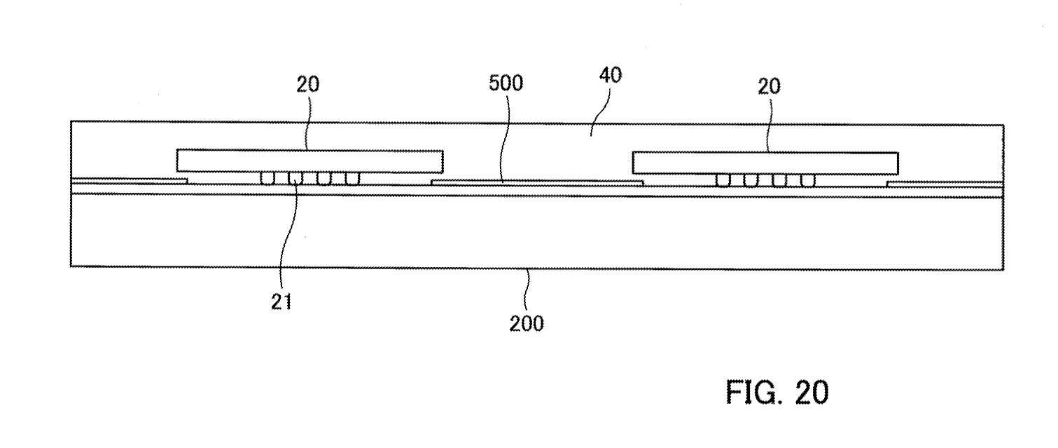

As illustrated in FIG. 20, a resin layer 40 is formed after the temporary affixing of the semiconductor chips 20 (Step S4).

The resin layer 40 is formed by, for example, placing a sheet-like seal on a side of the supporter 200 adjacent to the rear sides of the semiconductor chips 20 (opposite to those on which the COC connection terminals 21 are formed) temporarily affixed to the supporter 200 and by performing vacuum lamination (for example, 100° to 180° C.). The formation of the resin layer 40 is not limited to the above-described method, and the resin layer 40 may also be formed by, for example, compression molding using a liquid resin or by transfer molding.

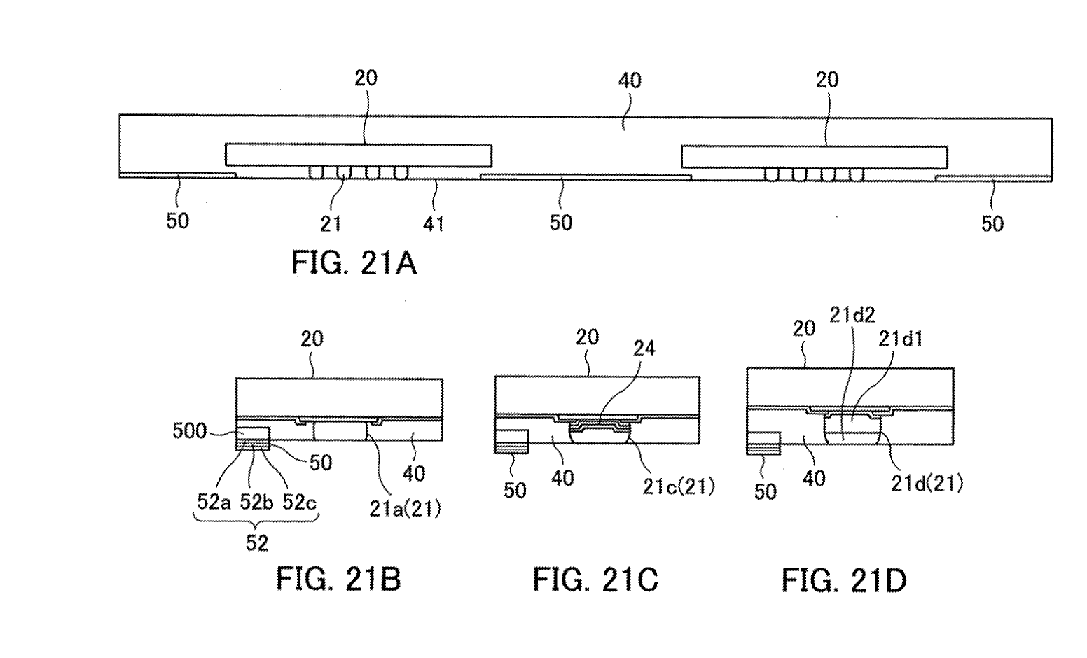

As illustrated in FIGS. 21A to 21D, the supporter 200 is removed, and surface treatment is performed after the formation of the resin layer 40 (Steps S5 and S6).

When a Cu/Ni supporter is used as the supporter 200, the Cu layer (first layer 201) is selectively wet-etched until the Ni layer (second layer 202) is exposed, and subsequently, the Ni layer exposed by the etching is selectively wet-etched until the wiring layer 500 is exposed. When a laminate including a supporter body (first layer 201) and an adhesive layer (second layer 202) formed thereon is used as the supporter 200, the supporter body is first removed from the adhesive layer, and subsequently, the adhesive layer remaining on the resin layer 40 is removed.

The COC connection terminals 21 and the wiring layer 500 are exposed by removing the supporter 200 as described above. A finishing layer 52 is formed on a surface of the wiring layer 500, which are exposed together with the COC connection terminals 21 as illustrated in FIGS. 21B, 21C, and 21D (the Au bump 21a, the solder bump 21c, and the pillar electrodes 21d, respectively) by laminating a Ni layer 52a, a palladium (Pd) layer 52b, and a Au layer 52c in this order. Alternatively, a solder layer may be used as the finishing layer 52. The finishing layer 52 may be formed by plating. A wiring layer 50 is formed by forming the finishing layer 52 on the wiring layer 500.

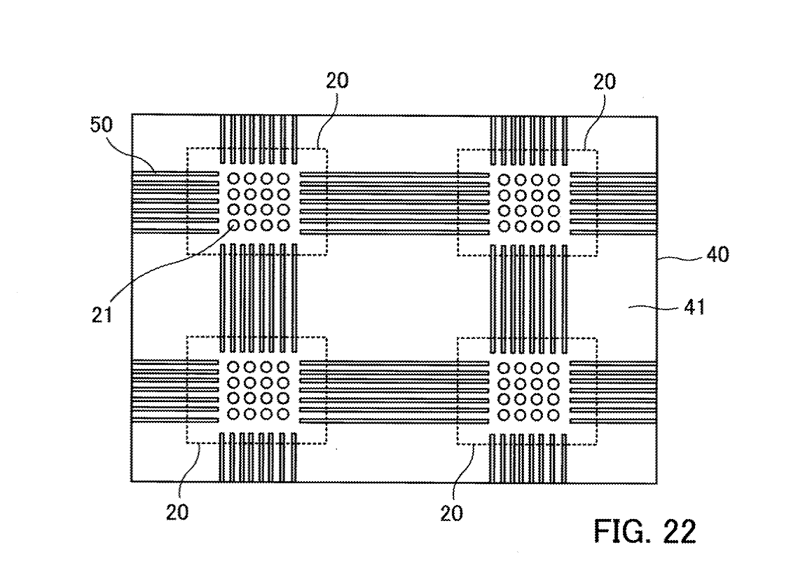

FIG. 22 illustrates a structure including the surface-treated wiring layer 50 (having the finishing layer 52 illustrated in FIGS. 21B to 21D) and the COC connection terminals 21 exposed through a surface 41 of the resin layer 40 obtained through the above-described steps.

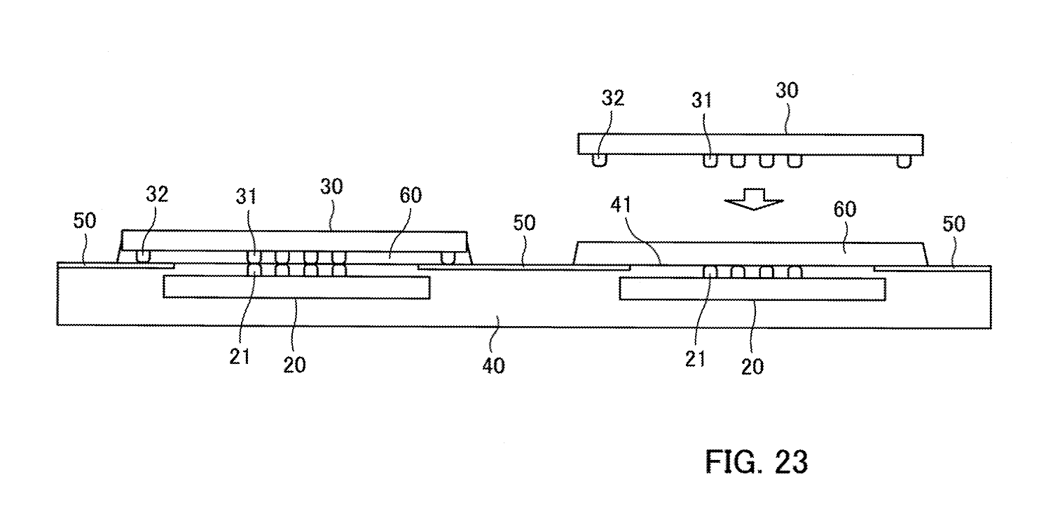

Next, the semiconductor chips 30 are mounted as illustrated in FIG. 23 (Step S7).

The semiconductor chips 30 are mounted on the surface 41 of the resin layer 40 by applying a filler resin 60 in chip mounting areas on the surface 41 and by placing the semiconductor chips 30 in the chip mounting areas in a face-down position. At this moment, the semiconductor chips 30 are flip-chip bonded such that the COC connection terminals 31 of the semiconductor chips 30 and the COC connection terminals 21 of the semiconductor chips 20 exposed through the resin layer 40 are connected to each other. At the same time, the COB connection terminals 32 of the semiconductor chip 30 are connected to the wiring layer 50 in the resin layer 40. The semiconductor chips 30 are mounted in this manner by, for example, heating at 200° C. to 300° C. under a pressure of 1 to 100 N.

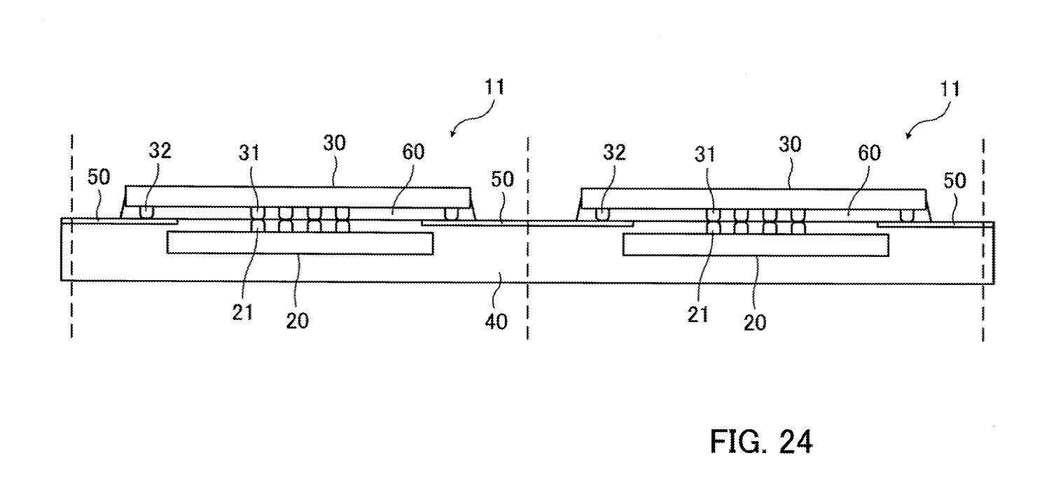

After mounting the semiconductor chips 30, the intermediate product is cut at positions between two adjacent semiconductor chips 30 (between two adjacent semiconductor chips 20; indicated by broken lines in FIG. 24) as illustrated in FIG. 24 so as to be divided (fragmented) into separate COC portions 11 (Step S8).

Each of the divided COC portions 11 is mounted on an interposer portion 70 with a die attachment member 80 interposed therebetween, and sealed by a sealing resin 100 after the connection to the interposer portion 70 using wires 90. Lastly, solder balls 72 are formed on the interposer portion 70. This completes the COC package 10 as illustrated in FIG. 2 (Step S9).

The method of forming the COC portion 11 and the COC package 10 including a set of semiconductor chips 20 and 30 has been described above as an example. In addition to this, COC portions and COC packages including a plurality of semiconductor chips mounted on the resin layer 40 (FIGS. 13A and 13B) or including a plurality of semiconductor chips embedded in the resin layer 40 (FIGS. 15A and 15B) may also be formed through procedures similar to that described above by following the above-described example. For example, when a plurality of semiconductor chips are embedded in the resin layer 40, the plurality of semiconductor chips are temporarily affixed onto the supporter 200 (FIGS. 19A to 19D), and a semiconductor chip to be connected thereto is flip-chip mounted to the plurality of semiconductor chips (FIG. 23). This method of temporarily affixing the plurality of semiconductor chips to the supporter 200 may reduce the mounting time compared with the case where the plurality of semiconductor chips are separately flip-chip mounted.

Even when a Si interposer (FIG. 14) is used instead of a semiconductor chip, the Si interposer may also be formed through the procedures similar to that described above by following the above-described example. When internally sealed terminals that connect terminals whose positions are shifted from each other are formed (FIGS. 16A and 16B), the internally sealed terminals (wiring layer) may be formed together with the wiring layer 500 in the step of forming the wiring layer 500 illustrated in FIG. 18.

The COC package 10 of the ball grid array (BGA) type having the solder balls 72 formed thereon is described in the example above. However, a COC package of the land grid array (LGA) type without such solder balls 72 may be produced.

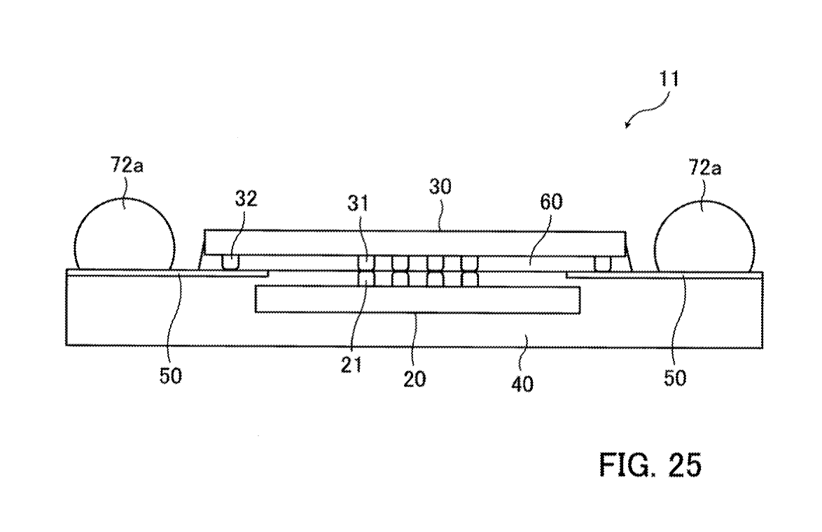

Modifications of the COC portion and the COC package will now be described with reference to FIGS. 25 to 27.

After the step illustrated in FIG. 24 (Step S9), for example, solder balls 72a may be formed on the wiring layer 50 as illustrated in FIG. 25 so as to form a COC portion 11 that is connectable to the outside.

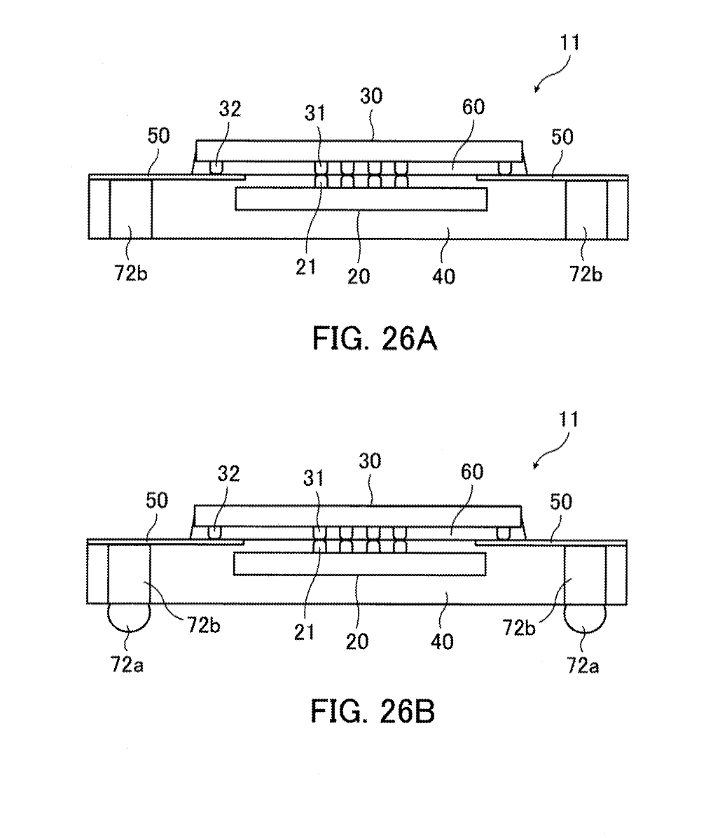

As illustrated in FIGS. 26A and 26B, for example, feed-through electrodes 72b extending to the wiring layer 50 may be formed in the resin layer 40. In this case, the COC portion 11 to be formed may be of the LGA type as illustrated in FIG. 26A, or may be of the BGA type on which the solder balls 72a are formed as illustrated in FIG. 26B.

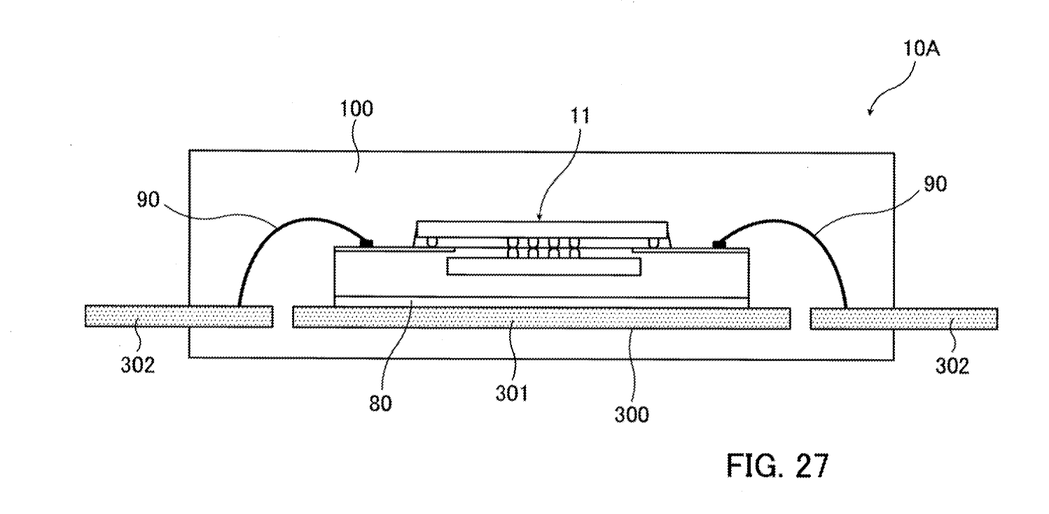

Although COC portion 11 included in the COC package 10 illustrated in FIG. 2 is mounted on a circuit board (tabular body) such as the interposer portion 70, a COC package 10A may be formed by mounting the COC portion on another tabular body such as a lead frame 300 as illustrated in FIG. 27. For example, the COC portion 11 is mounted above a die pad 301 of the lead frame 300 with the die attachment member 80 interposed therebetween, and is sealed using the sealing resin 100 after the COC portion 11 and leads 302 of the lead frame 300 are connected to each other by the wires 90.

The structures as illustrated in FIGS. 25 to 27 may be applied to the above-described COC portions 11A, 11B, and 11C in a similar manner.

In addition to these, a COC portion may include a plurality of semiconductor elements, a resin layer in which the semiconductor elements are embedded such that terminals of the semiconductor elements are exposed through the resin layer, and a plurality of semiconductor elements mounted on the resin layer. Furthermore, a COC package may include such a COC portion.

The semiconductor devices disclosed above may increase flexibility in selecting semiconductor elements to be used. In addition, the semiconductor devices may be produced more efficiently at low cost.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that various changes, substitutions, and alterations could be made hereto without departing from the spirit and scope of the invention.

What is claimed is:

1. A semiconductor device comprising:
a first semiconductor element having a first terminal;
a resin layer in which the first semiconductor element is embedded such that the first terminal is exposed through a first surface of the resin layer;
a wiring layer formed in the first surface of the resin layer; and
a second semiconductor element having a second terminal and a third terminal, the second terminal being formed on a surface of the second semiconductor element adjacent to the first surface and being connected to the first terminal, the third terminal being connected to the wiring layer.

2. The semiconductor device according to claim 1, wherein the wiring layer extends from a region connected to the third terminal to the outside of the second semiconductor element.

3. The semiconductor device according to claim 1, further comprising:
a third semiconductor element having a fifth terminal formed on a surface of the third semiconductor element adjacent to the first surface of the resin layer, wherein
the first semiconductor element has a fourth terminal exposed through the resin layer and connected to the fifth terminal.

4. The semiconductor device according to claim 1, further comprising:
a fourth semiconductor element having a sixth terminal and embedded in the resin layer such that the sixth terminal is exposed through the first surface of the resin layer, wherein
the second semiconductor element has a seventh terminal connected to the sixth terminal.

5. The semiconductor device according to claim 1, further comprising:
an eighth terminal formed in the first surface to connect the first terminal and the second terminal.

6. The semiconductor device according to claim 1, further comprising:
a tabular body having a conductive portion electrically connected to the wiring layer.

7. The semiconductor device according to claim 6, wherein the tabular body is a circuit board or a lead frame.

8. The semiconductor device according to claim 1, further comprising:
a sealing resin that seals the first semiconductor element, the resin layer, the wiring layer, and the second semiconductor element.

9. A method of manufacturing a semiconductor device comprising:
forming a wiring layer in a first area of a supporter;
placing a first semiconductor element having a first terminal in a second area of the supporter such that the first terminal is in contact with the second area;
embedding the wiring layer and the first semiconductor element on the supporter in a resin layer;
removing the supporter; and
mounting a second semiconductor element having a second terminal and a third terminal on a first surface of the resin layer, the first terminal being exposed through the first surface, such that the second terminal is connected to the first terminal and such that the third terminal is connected to the wiring layer.
